(19) United States
(12) Patent Application Publication
(10) Pub. No.: US 2014/0370691 A1
(43) Pub. Date: Dec. 18, 2014

(54) VAPOR PHASE GROWTH APPARATUS AND VAPOR PHASE GROWTH METHOD

(71) Applicant: NuFlare Technology, Inc., Kanagawa (JP)

(72) Inventors: Takumi YAMADA, Kanagawa (JP); Yuusuke SATO, Tokyo (JP)

(21) Appl. No.: 14/301,666

(22) Filed: Jun. 11, 2014

(30) Foreign Application Priority Data
Jun. 13, 2013 (JP) 2013-124848

(51) Int. Cl. H01L 21/02

(52) U.S. Cl. CPC H01L 21/0262
USPC 438/478; 118/715

(57) ABSTRACT

A vapor phase growth apparatus of an embodiment includes: a reaction chamber; a shower plate disposed in the upper portion of the reaction chamber to supply a gas into the reaction chamber; a support portion provided below the shower plate inside the reaction chamber to place a substrate thereon; a process gas supply line that supplies a process gas; and a purging gas supply line that supplies a gas obtained by mixing first and second purging gases selected from hydrogen and an inert gas. Then, an inner area of the shower plate is provided with process gas ejection holes, and an outer area of the shower plate is provided with purging gas election holes. Then, the process gas supply line is connected to the process gas ejection holes, and the purging gas supply line is connected to the purging gas ejection holes.

### CROSS-REFERENCE TO RELATED APPLICATION

This application is based upon and claims the benefit of priority from Japanese Patent Applications No. 2013-124848, filed on Jun. 13, 2013, the entire contents of which are incorporated herein by reference.

### FIELD OF THE INVENTION

Embodiments described herein relate generally to a vapor phase growth apparatus that forms a film by supplying a gas and a vapor phase growth method.

### BACKGROUND OF THE INVENTION

As a method of forming a high-quality semiconductor film, there is known an epitaxial growth technique of growing a single-crystal film on a substrate such as a wafer by the vapor phase growth. In a vapor phase growth apparatus that uses the epitaxial growth technique, a wafer is placed on a support portion inside a reaction chamber that is maintained in a normal pressure state or a reduced pressure state. Then, a process gas such as a source gas as a raw material for a film formation process is supplied from, for example, a shower plate of an upper portion of the reaction chamber to the surface of the wafer while heating the wafer. Thus, a thermal reaction of the source gas occurs on the surface of the wafer, and hence an epitaxial single-crystal film is formed on the surface of the wafer.

In recent years, a semiconductor device of GaN (gallium nitride) has been gaining attention as a material of a light emitting device or a power device. As the epitaxial growth technique that forms a GaN-based semiconductor, a metal organic chemical vapor deposition (MOCVD) is known. In the metal organic chemical vapor deposition, for example, organic metal such as trimethylgallium (TMG), trimethylindium (TMI), and trimethylaluminum (TMA) or ammonia (NH₃) is used as the source gas. Also, there is a case in which hydrogen (H₂) is used as a separation gas in order to suppress the reaction in the source gas.

In the epitaxial growth technique, it is desirable to suppress the deposition of the film on the side wall of the reaction chamber in order to reduce particles inside the reaction chamber and to form a low-defective film. For this reason, a purging gas is supplied along the side wall of the reaction chamber during the film formation process. JP 2008-244014 A discloses a method of supplying a gas obtained by mixing hydrogen, nitrogen, and argon as the purging gas.

### SUMMARY OF THE INVENTION

According to an embodiment, there is provided a vapor phase growth apparatus including: a reaction chamber; a support portion provided inside the reaction chamber, the support portion configured to place a substrate thereon; a first gas supply line supplying a first process gas; a second gas supply line supplying a second process gas; a purging gas supply line supplying a mixed gas obtained by mixing a first purging gas including at least one gas selected from hydrogen and an inert gas with a second purging gas including at least one gas selected from inert gases and having a molecular weight larger than that of the first purging gas; and a shower plate disposed in the upper portion of the reaction chamber, the shower plate configured to supply a gas into the reaction chamber, the shower plate including: a plurality of first lateral gas passages connected to the first gas supply line, the first lateral gas passages being disposed within a first horizontal plane, the first lateral gas passages extending in parallel to each other, a plurality of first longitudinal gas passages connected to the first lateral gas passages, the first longitudinal gas passages extend in a longitudinal direction, the first longitudinal gas passages including first gas election holes, at a reaction chamber side of the shower plate, a plurality of second lateral gas passages connected to the second gas supply line, the second lateral gas passages being disposed within a second horizontal plane above the first horizontal plane, the second lateral gas passages extending in parallel to each other in the same direction as that of the first lateral gas passages, a plurality of second longitudinal gas passages connected to the second lateral gas passages, the second longitudinal gas passages extending in the longitudinal direction while passing between the first lateral gas passages, the second longitudinal gas passages including second gas election holes at the reaction chamber side of the shower plate, and purging gas ejection holes connected to the purging gas supply line, the purging gas ejection holes being provided near the side wall of the reaction chamber in relation to the first and second gas ejection holes.

According to an embodiment, there is provided a vapor phase growth method using a vapor phase growth apparatus including a reaction chamber, a shower plate disposed in the upper portion of the reaction chamber so as to supply a gas into the reaction chamber, and a support portion provided below the shower plate inside the reaction chamber so as to place a substrate thereon, the method including: placing the substrate on the support portion; heating the substrate; ejecting a plurality of kinds of process gases for a film formation process from an inner area of the shower plate; ejecting a mixed gas obtained by mixing a first purging gas selected from hydrogen and an inert gas and having a molecular weight smaller than that of an average molecular weight of the plurality of kinds of process gases with a second purging gas having a molecular weight larger than the average molecular weight from an outer area of the shower plate; and forming a semiconductor film on the surface of the substrate.

### BRIEF DESCRIPTION OF THE DRAWINGS

FIG. 1 is a schematic cross-sectional view illustrating a vapor phase growth apparatus of a first embodiment;

FIG. 2 is a schematic top view illustrating a shower plate of the first embodiment;

FIG. 3 is a cross-sectional view taken along the line AA of the shower plate of FIG. 2;

FIGS. 4A, 4B, and 4C are cross-sectional views taken along the lines BB, CC, and DD of the shower plate of FIG. 2;

FIG. 5 is a schematic bottom view illustrating a shower plate of a first embodiment;

FIG. 6 is an explanatory diagram illustrating a vapor phase growth method of the first embodiment;

FIGS. 7A, 7B, and 7C are diagrams illustrating an action of the vapor phase growth method of the first embodiment;

FIG. 8 is a schematic cross-sectional view illustrating a vapor phase growth apparatus of a second embodiment;

FIG. 9 is a schematic top view illustrating a shower plate of a third embodiment;

FIG. 10 is a cross-sectional view taken along the line EE of the shower plate of FIG. 9;

FIGS. 11A, 11B, and 11C are cross-sectional views taken along the lines FF, GG, and HH of the shower plate of FIG. 9; and

FIG. 12 is a schematic bottom view illustrating the shower plate of the third embodiment.

### DETAILED DESCRIPTION OF THE EMBODIMENTS

Hereinafter, embodiments will be described with reference to the drawings.

Furthermore, in the specification, the gravity direction in the state where the vapor phase growth apparatus is provided so as to perform a film formation process is defined as the “down”, and the opposite direction thereof is defined as the “up”. Accordingly, the “lower portion” indicates the position of the gravity direction with respect to the reference, and the “downside” indicates the gravity direction with respect to the reference. Then, the “upper portion” indicates the position of the direction opposite to the gravity direction with respect to the reference, and the “upside” indicates the direction opposite to the gravity direction with respect to the reference. Further, the “longitudinal direction” indicates the gravity direction.

Further, in the specification, the “horizontal plane” indicates a plane perpendicular to the gravity direction.

Further, in the specification, the “process gas” generally corresponds to the gas used to form a film on a substrate, and corresponds to, for example, the concept including a source gas, a carrier gas, a separation gas, and the like.

Further, in the specification, the “purging gas” indicates the gas that is supplied to the outer periphery side of the substrate along the side wall of the reaction chamber in order to suppress the deposition of the film on the inner surface of the side wall (the inner wall) of the reaction chamber during the film formation process.

### First Embodiment

A vapor phase growth apparatus of the embodiment includes: a reaction chamber; a support portion that is provided inside the reaction chamber so as to place a substrate thereon; a first gas supply line that supplies a first process gas; a second gas supply line that supplies a second process gas; and a purging gas supply line that supplies a gas obtained by mixing a first purging gas including at least one gas selected from hydrogen and an inert gas with a second purging gas including at least one gas selected from inert gases and having a molecular weight larger than that of the first purging gas. Further, the vapor phase growth apparatus includes a shower plate that is disposed in the upper portion of the reaction chamber so as to supply a gas into the reaction chamber, the shower plate including: a plurality of first lateral gas passages that are connected to the first gas supply line and are disposed within a first horizontal plane so as to extend in parallel to each other, a plurality of first longitudinal gas passages that are connected to the first lateral gas passages so as to extend in the longitudinal direction and include first gas ejection holes at the side of the reaction chamber, a plurality of second lateral gas passages that are connected to the second gas supply line, are disposed within a second horizontal plane above the first horizontal plane, and extend in parallel to each other in the same direction as that of each of the first lateral gas passages, a plurality of second longitudinal gas passages that are connected to the second lateral gas passages, extend in the longitudinal direction while passing between the first lateral gas passages, and include second gas ejection holes at the side of the reaction chamber, and purging gas ejection holes that are connected to the purging gas supply line and are provided near the side wall of the reaction chamber in relation to the first and second gas ejection holes.

With the above-described configuration, the vapor phase growth apparatus of the embodiment may increase the arrangement density of the gas ejection holes by narrowing the gap between the gas ejection holes ejecting the process gas into the reaction chamber. At the same time, the vapor phase growth apparatus of the embodiment may equalize the flow amount distribution of the gas ejected from the gas ejection holes by increasing the cross-sectional area of the lateral gas passage so that the fluid resistance of the gas passage decreases until the process gas reaches the gas ejection hole. Thus, according to the vapor phase growth apparatus of the embodiment, it is possible to grow a film having excellent uniformity in film thickness or film quality on the substrate.

Further, a mixed gas obtained by mixing at least one first purging gas selected from hydrogen and an inert gas with the second purging gas having a molecular weight larger than that of the first purging gas is supplied as the purging gas. Accordingly, the average molecular weight of the process gas may become close to the average molecular weight of the mixed gas. Accordingly, the turbulence in flow at the boundary between the process gas and the purging gas is suppressed, and hence the deposition of the film on the shower plate or the side wall of the reaction chamber may be suppressed.

Hereinafter, a case will be described in which the epitaxial growth of GaN (gallium nitride) is performed by MOCVD (Metal Organic Chemical Vapor Deposition).

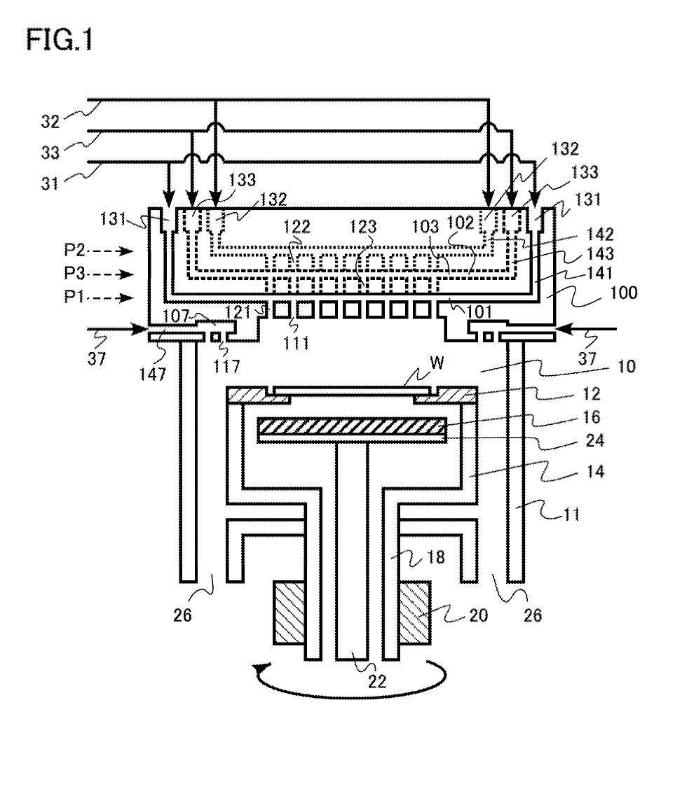

FIG. 1 is a schematic cross-sectional view illustrating the vapor phase growth apparatus of the embodiment. The vapor phase growth apparatus of the embodiment is a single wafer type epitaxial growth apparatus.

As illustrated in FIG. 1, the epitaxial growth apparatus of the embodiment includes a reaction chamber 10 that is formed as, for example, stainless cylindrical hollow body. The side surface of the reaction chamber 10 is a side wall 11. Then, the epitaxial growth apparatus includes a shower plate 100 that is disposed in the upper portion of the reaction chamber 10 and supplies a process gas into the reaction chamber 10.

Further, the epitaxial growth apparatus includes a support portion 12 that is disposed below the shower plate 100 inside the reaction chamber 10 while a semiconductor wafer (a substrate) W is placed thereon. The support portion 12 is, for example, an annular holder that has an opening formed at the center portion or a susceptor contacting the substantially entire rear surface of the semiconductor wafer W.

Further, a rotation unit 14 that rotates while placing the support portion 12 on the upper surface thereof and a heater that serves as a heating unit 16 heating the wafer W placed on the support portion 12 are provided below the support portion 12. Here, a rotation shaft 18 of the rotation unit 14 is connected to a rotational driving mechanism 20 located at the lower position. Then, the semiconductor wafer W may be rotated about the wafer center as the rotation center at, for example, several tens of rpm to several thousands of rpm by the rotational driving mechanism 20.

It is desirable that the diameter of the cylindrical rotation unit 14 be substantially equal to the outer peripheral diameter of the support portion 12. Furthermore, the rotation shaft 18 is rotatably provided at the bottom portion of the reaction chamber 10 through a vacuum seal member.

Then, the heating unit 16 is provided while being fixed onto a support base 24 fixed to a support shaft 22 penetrating the inside of the rotation shaft 18. Electric power is supplied to the heating unit 16 by a current introduction terminal and an electrode (not illustrated). The support base 24 is provided with, for example, a push-up pin (not illustrated) that is used to attach or detach the semiconductor wafer W to or from the annular holder.

Further, the bottom portion of the reaction chamber 10 is provided with a gas exhausting portion 26 that exhausts a reaction product obtained by the reaction of a source gas on the surface of the semiconductor wafer W and a residual gas of the reaction chamber 10 to the outside of the reaction chamber 10. Furthermore, the gas exhausting portion 26 is connected to a vacuum pump (not illustrated).

Then, the epitaxial growth apparatus of the embodiment includes a first gas supply line 31 that supplies a first process gas, a second gas supply line 32 that supplies a second process gas, and a third gas supply line 33 that supplies a third process gas.

Further, the epitaxial growth apparatus includes a purging gas supply line 37 that supplies a gas obtained by mixing the first and second purging gases including at least one gas selected from the hydrogen and the inert gas. The molecular weight of the second purging gas is larger than the molecular weight of the first purging gas. The inert gas is, for example, helium (He), nitrogen (N₂), or argon (Ar).

From the viewpoint of bringing the average molecular weight of the first, second, and third process gases flowing for the film formation process close to the average molecular weight of the mixed gas, it is desirable that the molecular weight of the first purging gas be smaller than the average molecular weight of the first, second, and third process gases and the molecular weight of the second purging gas be larger than the average molecular weight of the first, second, and third process gases. Accordingly, it is possible to bring the average molecular weight of the process gas close to the average molecular weight of the mixed gas by appropriately adjusting the mixing ratio between the first purging gas and the second purging gas.

It is desirable that the average molecular weight of the mixed gas be substantially equal to the average molecular weight of the process gas and the average flow rate of the purging gas be substantially equal to the average flow rate of the process gas. When the average molecular weight of the mixed gas is equal to or larger than 80% and equal to or smaller than 120% of the average molecular weight of the process gas, turbulence is hardly generated in the flow at the boundary between the purging gas and the process gas.

For example, in a case where a single-crystal film of GaN is formed on the semiconductor wafer W by MOCVD, for example, hydrogen (H₂) as a separation gas is supplied as the first process gas. Further, for example, ammonia (NH₃) as a source gas of nitrogen (N) is supplied as the second process gas. Further, for example, a gas obtained by diluting trimethylgallium (TNG) as organic metal and a source gas of Ga (gallium) by hydrogen (H₂) as a carrier gas is supplied as the third process gas.

Here, the separation gas as the first process gas is a gas that is ejected from first gas election holes 111 so as to separate the second process gas (here, ammonia) ejected from second gas ejection holes 112 and third process gas (here, TMG) ejected from third gas ejection holes 113. For example, it is desirable to use a gas that has insufficient reactivity with the second process gas and the third process gas.

The first purging gas is, for example, hydrogen (H₂) having a molecular weight of 2. Further, the second purging gas is, for example, nitrogen (N₂) having a molecular weight of 28. By mixing these gases, the average molecular weight of the mixed gas may be set to 2 to 28. Further, the first purging gas is, for example, helium (He) having a molecular weight of 4. Further, the second purging gas may be, for example, argon (Ar) having a molecular weight of 40.

When the average molecular weight of the mixed gas becomes close to the average molecular weight of the process gas, the turbulence in flow at the boundary therebetween is suppressed, and hence the deposition of the film on the side wall 11 of the reaction chamber 10 is suppressed.

Furthermore, in the single wafer type epitaxial growth apparatus illustrated in FIG. 1, a wafer exit/entrance and a gate valve (not illustrated) through which the semiconductor wafer is inserted and extracted are provided at the side wall 11 of the reaction chamber 10. Then, the semiconductor wafer W may be carried by a handling arm between, for example, a load lock chamber (not illustrated) connected to the gate valve and the reaction chamber 10. Here, for example, the handling arm formed of synthetic quart may be inserted into the space between the shower plate 100 and the wafer support portion 12.

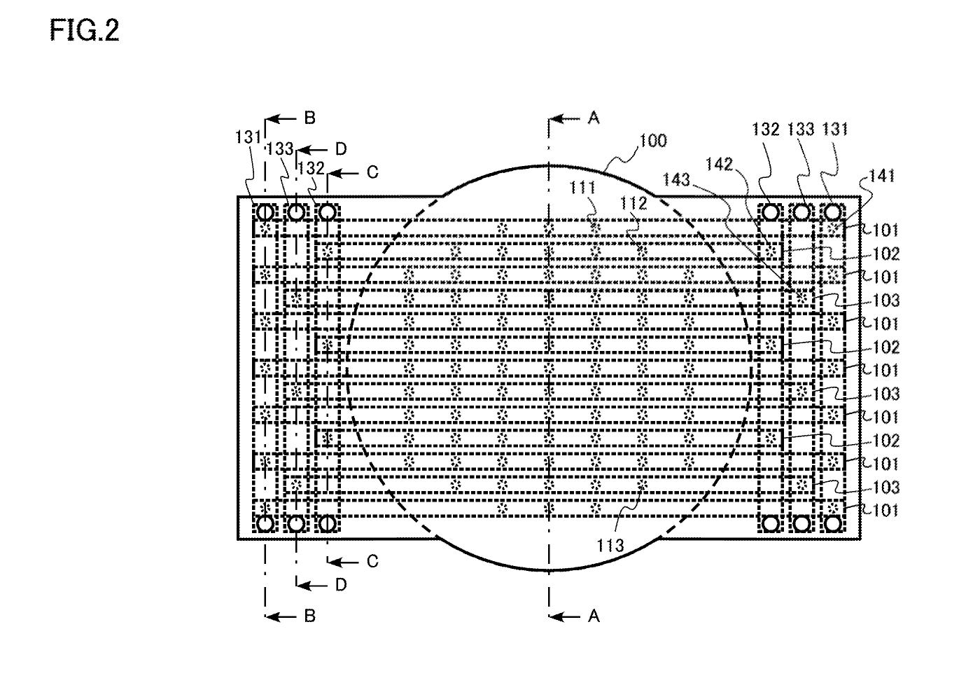

Hereinafter, the shower plate 100 of the embodiment will be described in detail. FIG. 2 is a schematic top view illustrating the shower plate of the embodiment. The passage structure inside the shower plate is depicted by the dashed line.

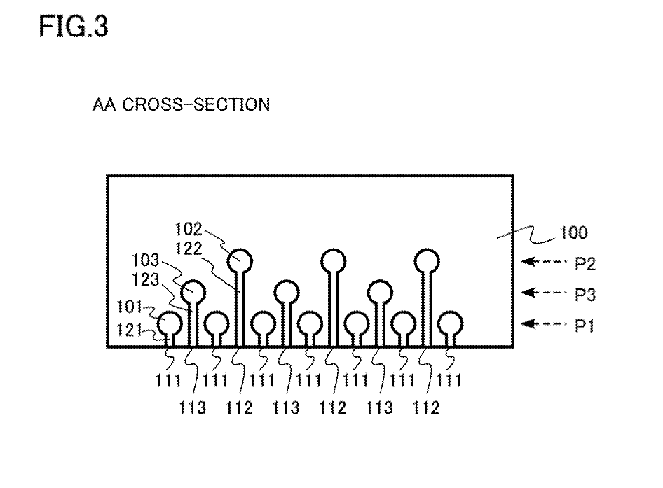

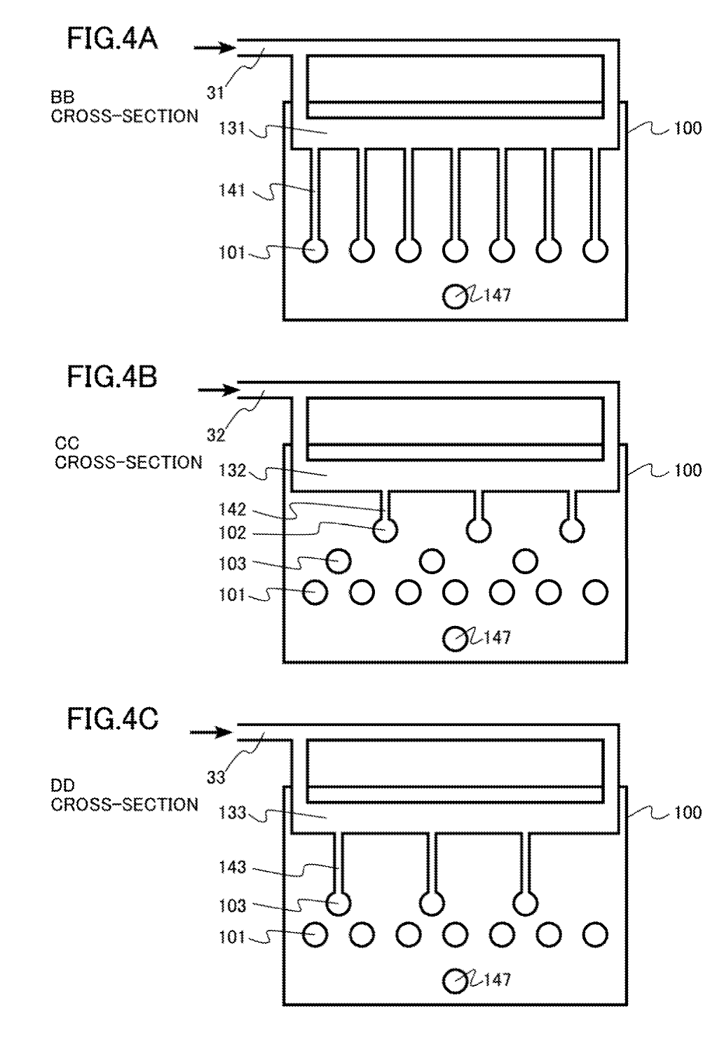

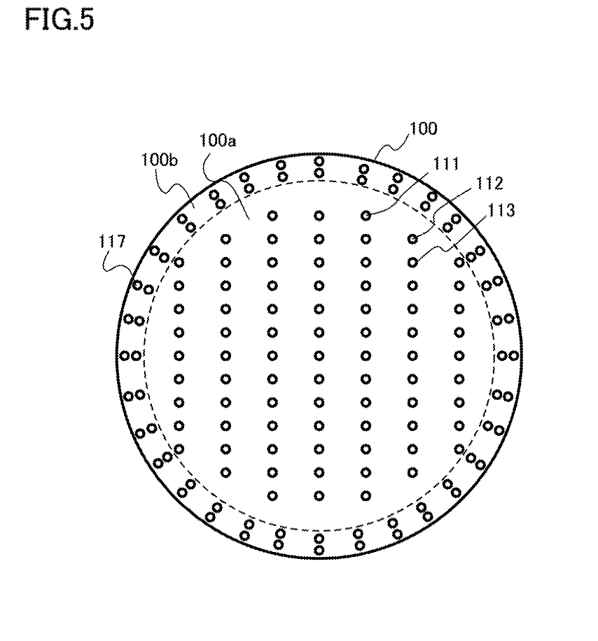

FIG. 3 is a cross-sectional view taken along the line AA of FIG. 2, and FIGS. 4A, 4B, and 4C are cross-sectional views taken along the lines BB, CC, and DD of FIG. 2. FIG. 5 is a schematic bottom view illustrating the shower plate of the embodiment.

The shower plate 100 has, for example, a plate shape with a predetermined thickness. The shower plate 100 is formed of, for example, a metal material such as stainless steel or aluminum alloy.

A plurality of first lateral gas passages 101, a plurality of second lateral gas passages 102, and a plurality of third lateral gas passages 103 are formed inside the shower plate 100. The plurality of first lateral gas passages 101 extend in parallel to each other within the first horizontal plane (P1). The plurality of second lateral gas passages 102 extend in parallel to each other while being disposed within the second horizontal plane (P2) above the first horizontal plane. The plurality of third lateral gas passages 103 extend in parallel to each other while being disposed within the third horizontal plane (P3) above the first horizontal plane and below the second horizontal plane.

A plurality of first longitudinal gas passages 121 are provided which are connected to the first lateral gas passages 101 so as to extend in the longitudinal direction and include the first gas ejection holes 111 at the side of the reaction chamber 10. Further, a plurality of second longitudinal gas passages 122 are provided which are connected to the second lateral gas passages 102 so as to extend in the longitudinal direction and include the second gas ejection holes 112 at the side of the reaction chamber 10. The second longitudinal gas passages 122 pass between the two first lateral gas passages 101. In addition, a plurality of third longitudinal gas passages 123 are provided which are connected to the third lateral gas passages 103 so as to extend in the longitudinal direction and include third gas ejection holes 113 at the side of the reaction chamber 10. The third longitudinal gas passages 123 pass between the first lateral gas passages 101.

The first lateral gas passages 101, the second lateral gas passages 102, and the third lateral gas passages 103 are lateral holes that are formed in the horizontal direction inside the plate-shaped shower plate 100. Further, the first longitudinal gas passages 121, the second longitudinal gas passages 122, and the third longitudinal gas passages 123 are longitudinal holes that are formed in the vertical (gravity) direction (the longitudinal direction or the perpendicular direction) inside the plate-shaped shower plate 100.

The inner diameters of the first, second, and third lateral gas passages 101, 102, and 103 are larger than the inner diameters of the first, second, and third longitudinal gas passages 121, 122, and 123 respectively corresponding thereto. In FIGS. 3, 4A, 4B, and 4C, the first, second, and third lateral gas passages 101, 102, and 103, the cross-sectional shapes of the first, second, and third longitudinal gas passages 121, 122, and 123 are circular, but the shape is not limited to the circular shape. For example, the other shapes such as an oval shape, a rectangular shape, and a polygonal shape may be employed. Further, the first, second, and third lateral gas passages 101, 102, and 103 may not have the same cross-sectional area. Further, the first, second, and third longitudinal gas passages 121, 122, and 123 may not have the same cross-sectional area.

The shower plate 100 includes a first manifold 131 that is connected to the first gas supply line 31 and is provided above the first horizontal plane (P1) and a first connection passage 141 that connects the first manifold 131 and each first lateral gas passage 101 at the end of the first lateral gas passage 101 and extends in the longitudinal direction.

The first manifold 131 has a function of distributing the first process gas supplied from the first gas supply line 31 to the plurality of first lateral gas passages 101 through the first connection passage 141. The first process gases distributed therefrom are introduced from the first gas ejection holes 111 of the plurality of first longitudinal gas passages 121 into the reaction chamber 10.

The first manifold 131 extends in a direction perpendicular to the first lateral gas passage 101, and has, for example, a hollow parallelepiped shape. In the embodiment, the first manifold 131 is provided in both ends of each first lateral gas passage 101, but may also be provided in at least one end thereof.

Further, the shower plate 100 includes a second manifold 132 that is connected to the second gas supply line 32 and is provided above the first horizontal plane (P1) and a second connection passage 142 that connects the second manifold 132 and each second lateral gas passage 102 at the end of the second lateral gas passage 102 and extends in the longitudinal direction.

The second manifold 132 has a function of distributing the second process gas supplied from the second gas supply line 32 to the plurality of second lateral gas passages 102 through the second connection passage 142. The second process gases distributed therefrom are introduced from the second gas ejection holes 112 of the plurality of second longitudinal gas passages 122 to the reaction chamber 10.

The second manifold 132 extends in a direction perpendicular to the second lateral gas passage 102, and has, for example, a hollow parallelepiped shape. In the embodiment, the second manifold 132 is provided in both ends of the second lateral gas passage 102, but may also be provided in at least one end thereof.

Further, the shower plate 100 includes a third manifold 133 that is connected to the third gas supply line 33 and is provided above the first horizontal plane (P1) and a third connection passage 143 that connects the third manifold 133 and each third lateral gas passage 103 at the end of the third lateral gas passage 103 and extends in the perpendicular direction.

The third manifold 133 has a function of distributing the third process gas supplied from the third gas supply line 33 to the plurality of third lateral gas passages 103 through the third connection passage 143. The third process gases distributed therefrom are introduced from the third gas ejection holes 113 of the plurality of third longitudinal gas passages 123 to the reaction chamber 10.

Further, as illustrated in FIG. 5, the shower plate 100 is divided into an inner area 100a provided with the first to third gas ejection holes 111 to 113 and an outer area 100b provided with purging gas ejection holes 117 that eject the purging gas. The purging gas ejection holes 117 are provided near the side wall 11 of the reaction chamber 10 in relation to the first to third gas ejection holes 111 to 113.

The purging gas ejection holes 117 are connected to a lateral purging gas passage 107. The purging gas passage 107 is formed as an annular hollow portion inside the outer area 100b of the shower plate 100. Then, the lateral purging gas passage 107 is connected to a purging gas connection passage 147. Further, a purging gas supply line 37 is connected to the purging gas connection passage 147. Accordingly, the purging gas supply line 37 is connected to the plurality of purging gas ejection holes 117 through the purging gas connection passage 147 and the lateral purging gas passage 107.

Furthermore, in FIGS. 4A, 4B, and 4C, the cross-sectional shape of the purging gas connection passage 147 is circular, but the other shapes such as an oval shape, a rectangular shape, and a polygonal shape may be used instead of the circular shape.

In general, from the viewpoint of ensuring the uniformity of the formation of the film, it is desirable that the flow amount of the process gas ejected from the gas ejection hole provided as a process gas supply port with respect to the shower plate into the reaction chamber 10 be uniform among the gas ejection holes. In the shower plate 100 according to the embodiment, the process gas is distributed in the plurality of lateral gas passages, is distributed in the longitudinal gas passages, and is ejected from the gas ejection holes. With this configuration, it is possible to improve the uniformity of the flow amount of the process gas elected from the gas ejection holes by a simple structure.

Further, it is desirable that the arrangement density of the gas ejection holes disposed from the viewpoint of the uniform formation of the film be set as large as possible. More than anything else, in the configuration provided with the plurality of lateral gas passages arranged in parallel to each other as in the embodiment, when the density of the gas ejection holes is increased, a trade-off occurs between the arrangement density of the gas ejection hole and the inner diameter of the lateral gas passage.

For this reason, the fluid resistance of the lateral gas passage increases with a decrease in the inner diameter of the lateral gas passage, and the flow amount distribution of the flow amount of the process gas ejected from the gas ejection hole with respect to the extension direction of the lateral gas passage increases. As a result, there is a concern that the uniformity of the flow amount of the process gas ejected from the respective gas election holes may be degraded.

According to the embodiment, a layered structure is formed such that the first lateral gas passages 101, the second lateral gas passages 102, and the third lateral gas passages 103 are formed in different horizontal planes. With this structure, the margin with respect to an increase in the inner diameter of the lateral gas passage is improved. Accordingly, it is possible to suppress an increase in the flow amount distribution caused by the inner diameter of the lateral gas passage while ensuring the density of the gas ejection holes.

Further, since a gas obtained by mixing the first and second purging gases selected from the hydrogen and the inert gas is supplied as the purging gas, the average molecular weight of the process gas may become close to the average molecular weight of the mixed gas. Accordingly, the turbulence in flow at the boundary between the process gas and the purging gas is suppressed, and hence the deposition of the film on the side wall of the reaction chamber may be suppressed.

Next, a vapor phase growth method of the embodiment will be described. The vapor phase growth method of the embodiment is a vapor phase growth method that uses a vapor phase growth apparatus including a reaction chamber, a shower plate that is disposed in the upper portion of the reaction chamber so as to supply a gas into the reaction chamber, and a support portion that is provided below the shower plate inside the reaction chamber so as to place a substrate thereon. Then, the vapor phase growth method includes: placing the substrate on the support portion; heating the substrate; and electing a plurality of kinds of process gases for a film formation process from an inner area of the shower plate. Further, the vapor phase growth method includes: ejecting a gas obtained by mixing a first purging gas selected from hydrogen and an inert gas and having a molecular weight smaller than the average molecular weight of the plurality of kinds of process gases with a second purging gas having a molecular weight larger than the average molecular weight from an outer area of the shower plate; and forming a semiconductor film on the surface of the substrate.

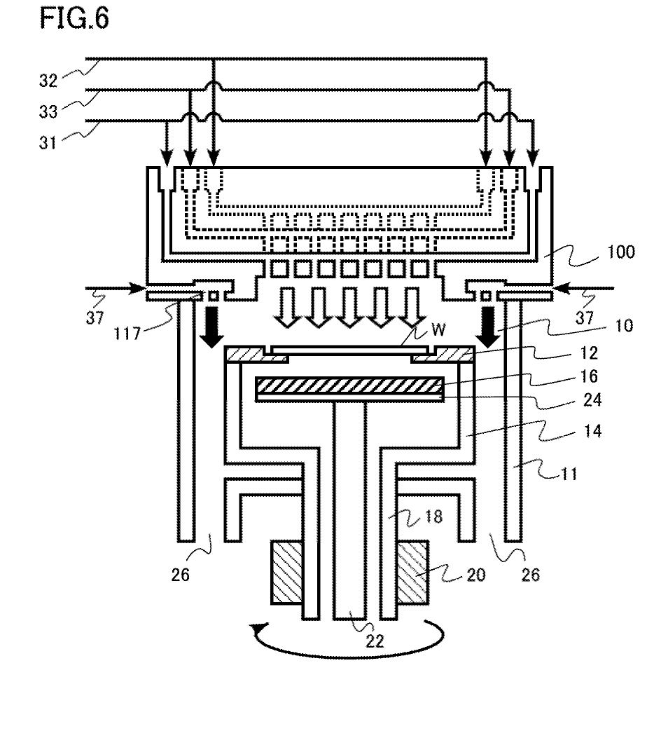

Hereinafter, a case will be described in which the epitaxial growth of GaN is performed by using the single wafer type epitaxial growth apparatus illustrated in FIGS. 1 to 5. Further, FIG. 6 is an explanatory diagram illustrating the vapor phase growth method of the embodiment.

In a state where a carrier gas is supplied to the reaction chamber 10, a vacuum pump (not illustrated) is operated so that the gas inside the reaction chamber 10 is exhausted from the gas exhausting portion 26, and the reaction chamber 10 is maintained in a predetermined pressure, the semiconductor wafer W is placed on the support portion 12 inside the reaction chamber 10. Here, the gate valve (not illustrated) of the wafer exit/entrance of the reaction chamber 10 is opened, and the semiconductor wafer W of the load lock chamber is carried into the reaction chamber 10 by the handling arm. Then, the semiconductor wafer W is placed on the support portion 12 through, for example, the push-up pin (not illustrated), the handling arm is returned to the load lock chamber, and the gate valve is closed.

Then, an exhausting operation is continued by the vacuum pump, and first to third predetermined process gases (indicated by the white arrow of FIG. 6) are ejected from the first to third gas ejection holes 111, 112, and 113 while rotating the rotation unit 14 at a necessary speed. The first process gas is supplied from the first gas supply line 31 through the first manifold 131, the first connection passage 141, the first lateral gas passages 101, and the first longitudinal gas passages 121, and is ejected from the first gas ejection holes 111 into the reaction chamber 10. Further, the second process gas is supplied from the second gas supply line 32 through the second manifolds 132, the second connection passage 142, the second lateral gas passages 102, and the second longitudinal gas passages 122, and is ejected from the second gas ejection holes 112 into the reaction chamber 10. Further, the third process gas is supplied from the third gas supply line 33 through the third manifold 133, the third connection passage 143, the third lateral gas passages 103, and the third longitudinal gas passages 123, and is elected from the third gas ejection holes 113 into the reaction chamber 10.

Further, a gas obtained by mixing the first purging gas having a molecular weight smaller than the average molecular weight of the first to third process gases with the second purging gas having a molecular weight larger than the average molecular weight is ejected as the purging gas from the purging gas ejection holes 117 along with the first to third process gases (see the black arrow of FIG. 6).

Here, the semiconductor wafer W placed on the support portion 12 is pre-heated to a predetermined temperature by the heating unit 16. Further, the heating output of the heating unit 16 is increased so that the temperature of the semiconductor wafer W increases to the epitaxial growth temperature.

In a case where the growth of GaN is performed on the semiconductor wafer W, for example, the first process gas is hydrogen as a separation gas, the second process gas is ammonia as a source gas of nitrogen, and the third process gas is TMG as a source gas of gallium diluted by hydrogen as a carrier gas. While the temperature increases, ammonia and TMG are not supplied to the reaction chamber 10.

When the temperature becomes the growth temperature, ammonia is supplied to the second gas ejection holes 112, TMG is supplied to the third gas ejection holes 113, and a single-crystal film of, for example, GaN (gallium nitride) is formed on the surface of the semiconductor wafer W by the epitaxial growth.

The first purging gas is, for example, hydrogen (H₂) having a molecular weight of 2. Further, the second purging gas is, for example, nitrogen (N₂) having a molecular weight of 28. Since hydrogen (H₂) having a molecular weight of 2 and nitrogen (N₂) having a molecular weight of 28 are mixed with each other, the average molecular weight of the mixed gas may become close to the average molecular weight of the process gas.

Then, when the epitaxial growth ends, the supply of TMG to the third gas ejection holes 113 stops, and the growth of the single-crystal film ends.

After the film process ends, the temperature of the semiconductor wafer W starts to fall. The temperature of the semiconductor wafer W decreases to a predetermined temperature, and then the supply of ammonia to the second gas ejection holes 112 is stopped. Here, for example, the rotation of the rotation unit 14 is stopped, the semiconductor wafer W having the single-crystal film formed thereon is placed on the support portion 12, and the heating output of the heating unit 16 is returned to the initial state so that the temperature decreases to the pre-heating temperature.

Next, after the temperature of the semiconductor wafer W is stabilized at a predetermined temperature, the semiconductor wafer W is attached to or detached from the support portion 12 by, for example, the push-up pin. Then, the gate valve is opened again, the handling arm is inserted between the shower plate 100 and the support portion 12, and then the semiconductor wafer W is loaded thereon. Then, the handling arm that loads the semiconductor wafer W thereon is returned to the load lock chamber.

As described above, each film formation process for the semiconductor wafer W ends. In succession, for example, the film formation process on the other semiconductor wafer W may be performed according to the same process sequence as the above-described one.

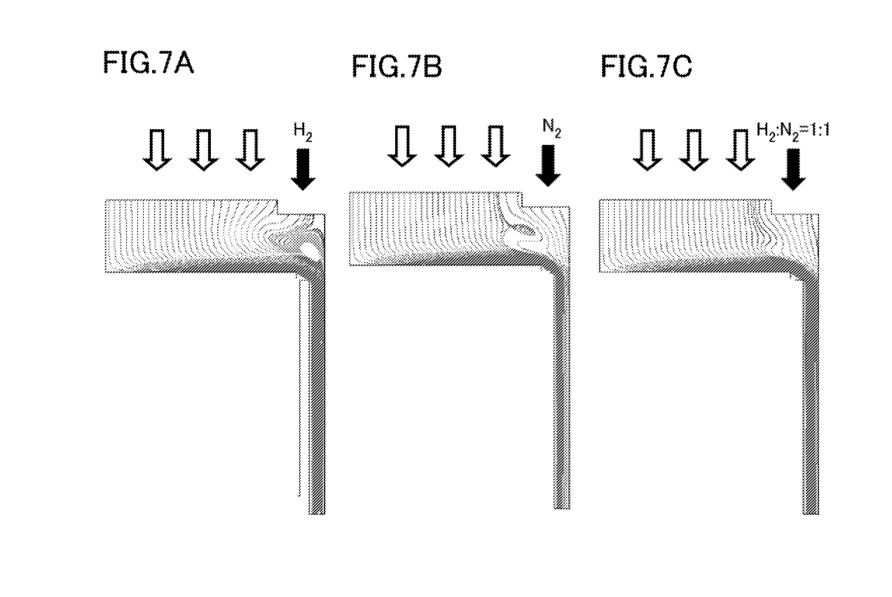

FIGS. 7A, 7B, and 7C are diagrams illustrating the action of the vapor phase growth method of the embodiment. Here, the flow rate distribution of the process gas and the purging gas is illustrated. FIG. 7A illustrates a case where only hydrogen is used as the purging gas (the black arrow of the drawing), FIG. 7B illustrates a case where only nitrogen is used as the purging gas, and FIG. 7C illustrates a case where a gas obtained by mixing hydrogen and nitrogen at the mixing ratio in which the gas has the same molecular weight as that of the process gas is supplied as the purging gas.

Here, the process gas (the white arrow of the drawing) is TMG as the source gas of gallium that is diluted by hydrogen as the separation gas, ammonia as the source gas of nitrogen, and hydrogen as the carrier gas. The average molecular weight of the plurality of kinds of process gases is larger than the molecular weight of 2 of hydrogen and is smaller than the molecular weight of 28 of nitrogen.

In the case of FIGS. 7A and 7B of the single gas, the flow at the boundary between the process gas (the white arrow of the drawing) and the purging gas (the black arrow of the drawing) becomes turbulent. Meanwhile, in the case of FIG. 7C of the mixed gas, the flow at the boundary between the process gas (the white arrow of the drawing) and the purging gas (the black arrow of the drawing) substantially does not become turbulent. Accordingly, it is understood that the flow of the process gas toward the side wall of the reaction chamber is suppressed in the case of FIG. 7C compared to the cases of FIGS. 7A and 7B.

In the vapor phase growth method of the embodiment, since the average molecular weight of the process gas becomes close to the average molecular weight of the purging gas, the deposition of the film on the side wall of the reaction chamber is suppressed. Accordingly, the generation of particles or dust inside the reaction chamber is suppressed. Accordingly, it is possible to form a low-defective film on the substrate.

Furthermore, it is desirable that the average molecular weight of the mixed gas of the first and second purging gases be equal to or larger than 80% and equal to or smaller than 120% of the average molecular weight of the first to third process gases. It is more desirable that the average molecular weight of the mixed gas be substantially equal to the average molecular weight of the process gas. In a case where the growth of InGaN is performed after the growth of GaN, the carrier gas is set as N₂. In such a case, the flow rate ratio of the mixed gas of the first and second purging gases is changed in accordance with the average molecular weight of the process gas.

### Second Embodiment

A vapor phase growth apparatus of the embodiment is the same as that of the first embodiment except that the vapor phase growth apparatus of the embodiment further includes: a first purging gas supply line that is connected to the purging gas supply line, includes a first mass flow controller, and supplies the first purging gas; a second purging gas supply line that is connected to the purging gas supply line, includes a second mass flow controller, and supplies the second purging gas; and a control unit that controls the first mass flow controller and the second mass flow controller. Accordingly, the same point as that of the first embodiment will not be described.

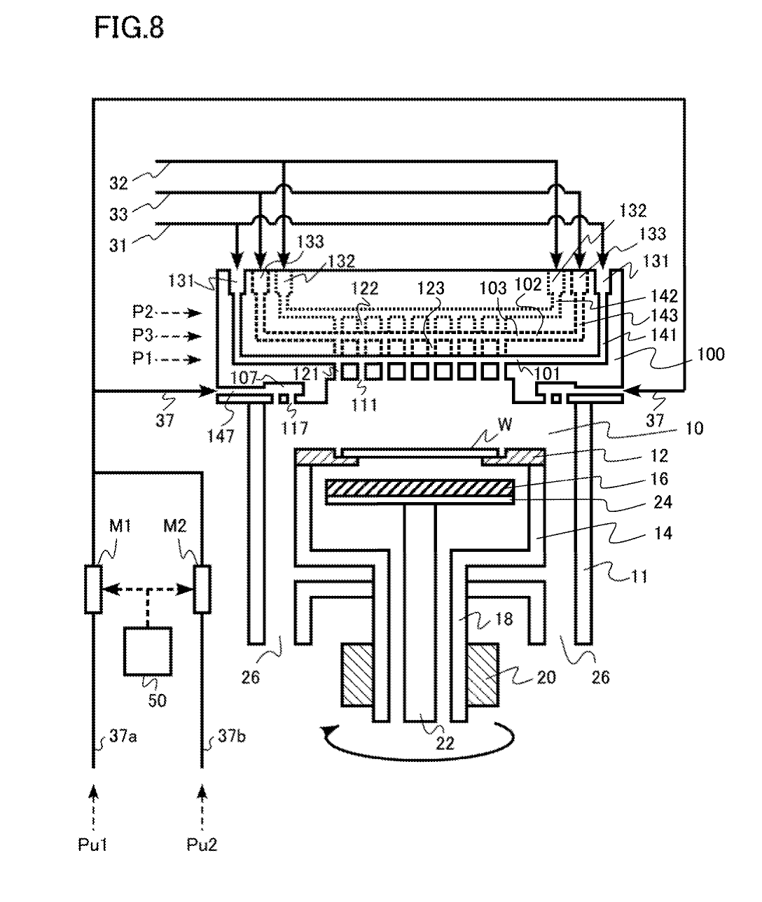

FIG. 8 is a schematic cross-sectional view illustrating the vapor phase growth apparatus of the embodiment. The vapor phase growth apparatus of the embodiment is a single wafer type epitaxial growth apparatus.

As illustrated in FIG. 8, the epitaxial growth apparatus of the embodiment includes: a first purging gas supply line 37a that is connected to a purging gas supply line 37, includes a first mass flow controller M1; a second purging gas supply line 37b that is connected to the purging gas supply line 37 and includes a second mass flow controller M2, and a control unit 50 that controls the first mass flow controller M1 and the second mass flow controller M2.

The first purging gas supply line 37a supplies a first purging gas (Pu1). The flow amount of the first purging gas is controlled by the first mass flow controller M1. Further, the second purging gas supply line 37b supplies a second purging gas (Pu2). The flow amount of the second purging gas is controlled by the second mass flow controller M2. The first purging gas and the second purging gas are mixed with each other so as to become a mixed gas after the flow amounts of the first purging gas and the second purging gas are controlled by the first and second mass flow controllers.

The control unit 50 controls the first mass flow controller M1 and the second mass flow controller M2 by transmitting, for example, a control signal. Accordingly, the average molecular weight of the purging gas supplied to the reaction chamber 10 is changed by changing the flow amount of the first purging gas and the flow amount of the second purging gas. The control unit 50 is configured as, for example, hardware such as an electronic circuit or a combination of hardware and software.

The control unit 50 changes the average molecular weight of the purging gas so that the average molecular weight becomes close to the average molecular weight of the process gas when the average molecular weight of the process gas is changed by a change in type of the process gas supplied to the reaction chamber 10 during the film formation process.

For example, in a case where the growth of GaN is performed on the substrate and then the growth of InGaN is performed in succession, the average molecular weight of the process gas changes. The control unit 50 controls the first mass flow controller M1 and the second mass flow controller M2 so that the average molecular weight of the purging gas becomes close to the average molecular weight of the process gas used for forming the film of InGaN.

The control unit 50 may simultaneously control, for example, the mass flow controllers respectively provided in the first gas supply line 31 supplying the first process gas, the second gas supply line 32 supplying the second process gas, and the third gas supply line 33 supplying the third process gas. With this configuration, for example, the flow amount of the process gas and the flow amount of the purging gas are controlled in an interlocked state. By this control, the average molecular weight of the purging gas may be changed while being interlocked with a change in the average molecular weight of the process gas.

Further, for example, the information on a change in the average molecular weight of the first, second, and third process gases may be transmitted from the control unit controlling the mass flow controllers respectively provided in the first gas supply line 31, the second gas supply line 32, and the third gas supply line 33 to the control unit 50. Even by this configuration, the average molecular weight of the purging gas may be changed while being interlocked with a change in the average molecular weight of the process gas.

According to the embodiment, even when the average molecular weight of the process gas changes during the film formation process, the average molecular weight of the purging gas may be also changed in the same direction. Accordingly, the deposition of the film on the side wall of the reaction chamber is suppressed, and hence the generation of particles or dust inside the reaction chamber is suppressed. Accordingly, it is possible to form a low-defective film on the substrate.

### Third Embodiment

A vapor phase growth apparatus of the embodiment includes: a reaction chamber; a support portion that is provided inside the reaction chamber so as to place a substrate thereon; a first gas supply line that supplies a first process gas; a second gas supply line that supplies a second process gas; and a purging gas supply line that supplies a gas obtained by mixing a first purging gas including at least one gas selected from hydrogen and an inert gas with a second purging gas including at least one gas selected from inert gases and having a molecular weight larger than that of the first purging gas. Further, the vapor phase growth apparatus includes a shower plate that is disposed in the upper portion of the reaction chamber so as to supply a gas into the reaction chamber. Then, an inner area of the shower plate is provided with process gas ejection holes, and an outer area of the shower plate is provided with purging gas ejection holes. Then, the process gas supply line is connected to the process gas ejection holes, and the purging gas supply line is connected to the purging gas ejection holes.

The vapor phase growth apparatus of the embodiment is the same as that of the first or second embodiment except that the passage of the process gas inside the shower plate is not limited. Accordingly, the same point as that of the first or second embodiment will not be described.

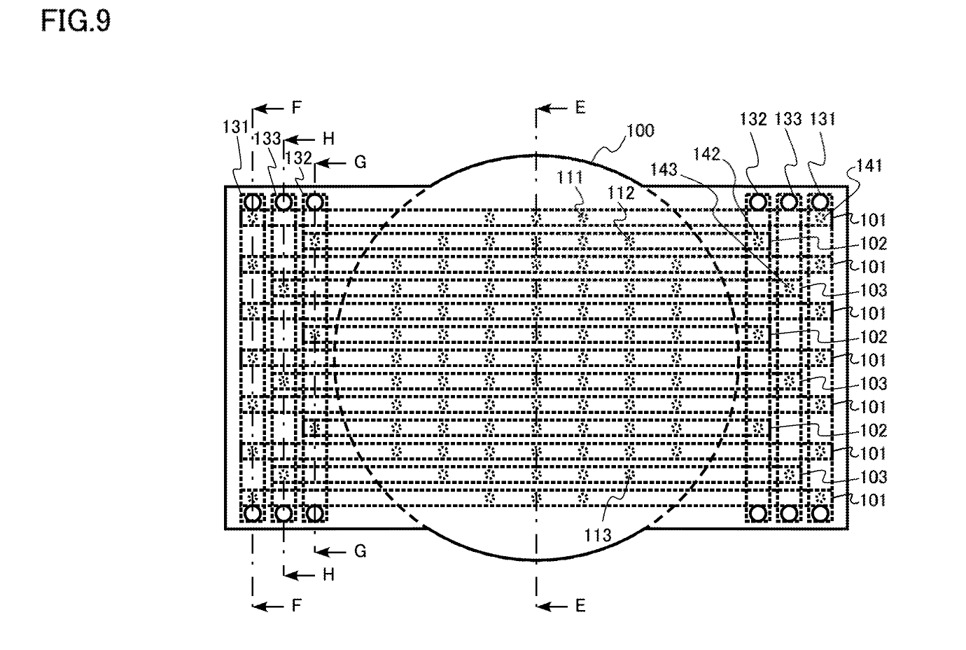

Hereinafter, the shower plate 100 of the embodiment will be described in detail. FIG. 9 is a schematic top view illustrating the shower plate of the embodiment. The passage structure inside the shower plate is indicated by the dashed line.

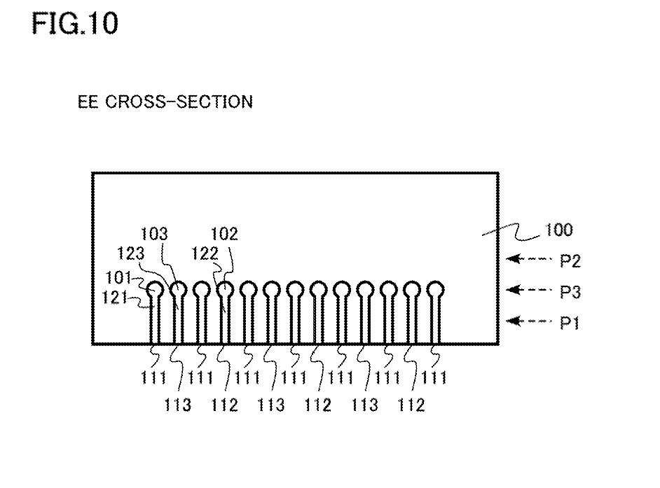

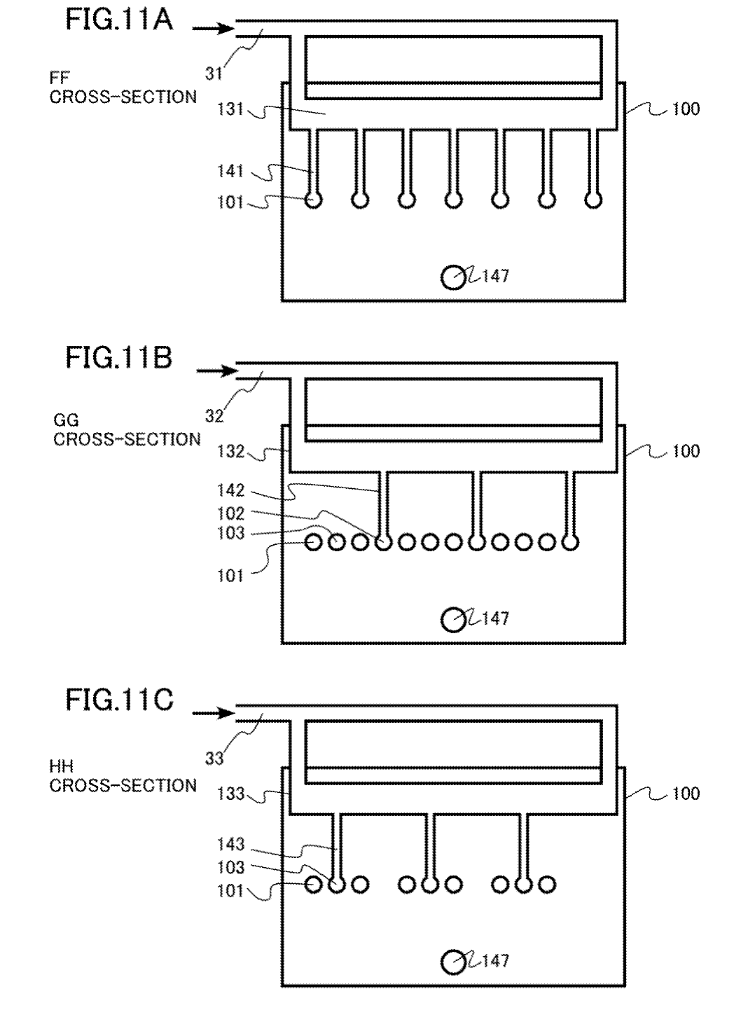

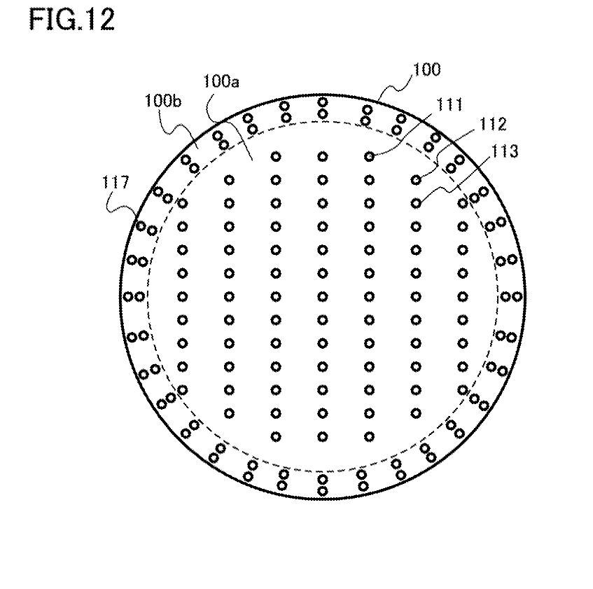

FIG. 10 is a cross-sectional view taken along the line EE of FIG. 9, and FIGS. 11A, 11B, and 11C are cross-sectional views taken along the lines FF, GG, and HH of FIG. 9. FIG. 12 is a schematic bottom view illustrating the shower plate of the embodiment.

The shower plate 100 has, for example, a plate shape with a predetermined thickness. The shower plate 100 is formed of, for example, a metal material such as stainless steel or aluminum alloy.

The plurality of first lateral gas passages 101, the plurality of second lateral gas passages 102, and the plurality of third lateral gas passages 103 are formed inside the shower plate 100. The plurality of first lateral gas passages 101, the plurality of second lateral gas passages 102, and the plurality of third lateral gas passages 103 extend in parallel to each other while being disposed within the same horizontal plane.

Then, the plurality of first longitudinal gas passages 121 are provided which are connected to the first lateral gas passages 101 so as to extend in the longitudinal direction and include first gas ejection holes 111 at the side of the reaction chamber 10. Further, the plurality of second longitudinal gas passages 122 are provided which are connected to the second lateral gas passages 102 so as to extend in the longitudinal direction and include second gas ejection holes 112 at the side of the reaction chamber 10. In addition, the plurality of third longitudinal gas passages 123 are provided which are connected to the third lateral gas passages 103 so as to extend in the longitudinal direction and include third gas ejection holes 113 at the side of the reaction chamber 10.

The first lateral gas passages 101, the second lateral gas passages 102, and the third lateral gas passages 103 are lateral holes that are formed in the horizontal direction inside the plate-shaped shower plate 100. Further, the first longitudinal gas passages 121, the second longitudinal gas passages 122, and the third longitudinal gas passages 123 are longitudinal holes that are formed in the vertical (gravity) direction (the longitudinal direction or the perpendicular direction) inside the plate-shaped shower plate 100.

The inner diameters of the first, second, and third lateral gas passages 101, 102, and 103 are larger than the inner diameters of the first, second, and third longitudinal gas passages 121, 122, and 123 respectively corresponding thereto. In FIGS. 10, 11A, 11B, and 11G, the first, second, and third lateral gas passages 101, 102, and 103, the cross-sectional shapes of the first, second, and third longitudinal gas passages 121, 122, and 123 are circular, but the shape is not limited to the circular shape. For example, the other shapes such as an oval shape, a rectangular shape, and a polygonal shape may be employed. Further, the first, second, and third lateral gas passages 101, 102, and 103 may not have the same cross-sectional area. Further, the first, second, and third longitudinal gas passages 121, 122, and 123 may not have the same cross-sectional area.

The shower plate 100 includes a first manifold 131 that is connected to the first gas supply line 31 and is provided above the first horizontal plane (P1) and a first connection passage 141 that connects the first manifold 131 and each first lateral gas passage 101 at the end of the first lateral gas passage 101 and extends in the longitudinal direction.

The first manifold 131 has a function of distributing the first process gas supplied from the first gas supply line 31 to the plurality of first lateral gas passages 101 through the first connection passage 141. The first process gases distributed therefrom are introduced from the first gas ejection holes 111 of the plurality of first longitudinal gas passages 121 into the reaction chamber 10.

The first manifold 131 extends in a direction perpendicular to the first lateral gas passage 101, and has, for example, a hollow parallelepiped shape. In the embodiment, the first manifold 131 is provided in both ends of each first lateral gas passage 101, but may be provided in at least one end thereof.

Further, the shower plate 100 includes a second manifold 132 that is connected to the second gas supply line 32 and is provided above the first horizontal plane (P1) and a second connection passage 142 that connects the second manifold 132 and each second lateral gas passage 102 at the end of the second lateral gas passage 102 and extends in the longitudinal direction.

The second manifold 132 has a function of distributing the second process gas supplied from the second gas supply line 32 to the plurality of second lateral gas passages 102 through the second connection passage 142. The second process gases distributed therefrom are introduced from the second gas ejection holes 112 of the plurality of second longitudinal gas passages 122 to the reaction chamber 10.

The second manifold 132 extends in a direction perpendicular to the second lateral gas passage 102, and has, for example, a hollow parallelepiped shape. In the embodiment, the second manifold 132 is provided in both ends of the second lateral gas passage 102, but may be provided in at least one end thereof.

Further, the shower plate 100 includes a third manifold 133 that is connected to the third gas supply line 33 and is provided above the first horizontal plane (P1) and a third connection passage 143 that connects the third manifold 133 and each third lateral gas passage 103 at the end of the third lateral gas passage 103 and extends in the perpendicular direction.

The third manifold 133 has a function of distributing the third process gas supplied from the third gas supply line 33 to the plurality of third lateral gas passages 103 through the third connection passage 143. The third process gases distributed therefrom are introduced from the third gas ejection holes 113 of the plurality of third longitudinal gas passages 123 to the reaction chamber 10.

Further, as illustrated in FIG. 12, the shower plate 100 is divided into an inner area 100a provided with the first to third gas ejection holes 111 to 113 and an outer area 100b provided with purging gas ejection holes 117 that eject the purging gas. The purging gas ejection holes 117 are provided near the side wall 11 of the reaction chamber 10 in relation to the first to third gas ejection holes 111 to 113.

The purging gas ejection holes 117 are connected to a lateral purging gas passage 107. The purging gas passage 107 is formed as an annular hollow portion inside the outer area 100b of the shower plate 100. Then, the lateral purging gas passage 107 is connected to a purging gas connection passage 147. Further, a purging gas supply line 37 is connected to the purging gas connection passage 147. Accordingly, the purging gas supply line 37 is connected to the plurality of purging gas ejection holes 117 through the purging gas connection passage 147 and the lateral purging gas passage 107.

Furthermore, in FIGS. 11A, 11B, and 11C, the cross-sectional shape of the purging gas connection passage 147 is circular, but the other shapes such as an oval shape, a rectangular shape, and a polygonal shape may be used instead of the circular shape.

A vapor phase growth method of the embodiment is the same as that of the first or second embodiment.

Even in the vapor phase growth apparatus and the vapor phase growth method of the embodiment, the deposition of the film on the side wall of the reaction chamber is suppressed in a manner such that the average molecular weight of the process gas becomes close to the average molecular weight of the purging gas. Accordingly, the generation of particles or dust inside the reaction chamber is suppressed. Accordingly, it is possible to form a low-defective film on the substrate.

Furthermore, it is desirable that the process gas includes ammonia and the first and second purging gases be hydrogen and nitrogen.

Further, it is desirable that the molecular weight of the first purging gas be smaller than the average molecular weight of the process gas and the molecular weight of the second purging gas be larger than the average molecular weight of the process gas.

Further, it is desirable that the average molecular weight of the mixed gas of the first and second purging gases be equal to or larger than 80% and equal to or smaller than 120% of the average molecular weight of the process gas. It is more desirable that the average molecular weight of the mixed gas be substantially equal to the average molecular weight of the process gas. In a case where the average molecular weight of the process gas is changed, the mixing ratio between the first purging gas and the second purging gas is changed.

As described above, the embodiments have been described with reference to the specific examples. However, the above-described embodiments are merely examples, and do not limit the present disclosure. Further, the components of the embodiments may be appropriately combined with each other.

For example, in the embodiments, a case has been described in which passages such as a lateral gas passage are provided as three kinds, but the passages such as a lateral gas passage may be provided as four kinds or more, or two kinds.

Further, for example, in the embodiments, a case has been described in which the single-crystal film of GaN (gallium nitride) is formed, but the embodiments may be also applied to, for example, the case where the single-crystal film of Si (silicon) or SiC (silicon carbide) is formed.

Further, in the embodiments, an example of the single wafer type epitaxial apparatus that forms a film for each wafer has been described, but the vapor phase growth apparatus is not limited to the single wafer type epitaxial apparatus. For example, the embodiments may be also applied to a planetary CVD apparatus that simultaneously forms a film on a plurality of wafers that revolve in a spinning state.

In the embodiments, the apparatus configuration or the manufacturing method which is not directly necessary for the description of the invention is not described, but the apparatus configuration or the manufacturing method which needs to be used may be appropriately selected and used. In addition, all vapor phase growth apparatuses and all vapor phase growth methods that include the components of the invention and may be appropriately modified in design by the person skilled in the art are included in the scope of the invention. The scope of the invention is defined by the claims and the scope of the equivalent thereof.

What is claimed is:

1. A vapor phase growth apparatus comprising:
a reaction chamber;
a support portion provided inside the reaction chamber, the support portion configured to place a substrate thereon;
a first gas supply line supplying a first process gas;
a second gas supply line supplying a second process gas;
a purging gas supply line supplying a mixed gas obtained by mixing a first purging gas including at least one gas selected from hydrogen and an inert gas with a second purging gas including at least one gas selected from inert gases and having a molecular weight larger than that of the first purging gas; and
a shower plate disposed in the upper portion of the reaction chamber, the shower plate configured to supply a gas into the reaction chamber, the shower plate including:
a plurality of first lateral gas passages connected to the first gas supply line, the first lateral gas passages being disposed within a first horizontal plane, the first lateral gas passages extending in parallel to each other,
a plurality of first longitudinal gas passages connected to the first lateral gas passages, the first longitudinal gas passages extending in a longitudinal direction, the first longitudinal gas passages including first gas ejection holes, at a reaction chamber side of the shower plate,
a plurality of second lateral gas passages connected to the second gas supply line, the second lateral gas passages being disposed within a second horizontal plane above the first horizontal plane, the second lateral gas passages extending in parallel to each other in the same direction as that of the first lateral gas passages,
a plurality of second longitudinal gas passages connected to the second lateral gas passages, the second longitudinal gas passages extending in the longitudinal direction while passing between the first lateral gas passages, the second longitudinal gas passages including second gas ejection holes at the reaction chamber side of the shower plate, and
purging gas ejection holes connected to the purging gas supply line, the purging gas ejection holes being provided near the side wall of the reaction chamber in relation to the first and second gas ejection holes.

2. The apparatus according to claim 1,
wherein the first or second process gas is ammonia, the first purging gas is hydrogen, and the second purging gas is nitrogen.

3. The apparatus according to claim 1, further comprising:
a first purging gas supply line connected to the purging gas supply line, the first purging gas supply line having a first mass flow controller, the first purging gas supply line supplying the first purging gas;
a second purging gas supply line connected to the purging gas supply line, the second purging gas supply line having a second mass flow controller, the second purging gas supply line supplying the second purging gas; and
a control unit controlling the first mass flow controller and the second mass flow controller.

4. The apparatus according to claim 1, further comprising:
a third gas supply line supplying a third process gas,
wherein the shower plate includes:
a plurality of third lateral gas passages connected to the third gas supply line, the third lateral gas passages being disposed within a third horizontal plane above the first horizontal plane and below the second horizontal plane, the third lateral gas passages extending in parallel to each other in the same direction as that of the first lateral gas passages, and
a plurality of third longitudinal gas passages connected to the third lateral gas passages, the third longitudinal gas passages extending in the longitudinal direction while passing between the first lateral gas passages, the third longitudinal gas passages including third gas ejection holes at the reaction chamber side of the shower plate.

5. The apparatus according to claim 4,
wherein one of the first, second, and third process gases is ammonia, another one thereof is a gas including organic metal, the other one thereof is hydrogen, the first purging gas is hydrogen, and the second purging gas is nitrogen.

6. A vapor phase growth apparatus comprising:
a reaction chamber;
a support portion provided inside the reaction chamber, the support portion configured to place a substrate thereon;
a first gas supply line supplying a first process gas;
a second gas supply line supplying a second process gas;
a purging gas supply line supplying a mixed gas obtained by mixing a first purging gas including at least one gas selected from hydrogen and an inert gas with a second purging gas including at least one gas selected from inert gases and having a molecular weight larger than that of the first purging gas; and
a shower plate disposed in the upper portion of the reaction chamber, the shower plate configured to supply a gas into the reaction chamber, the shower plate including:
first gas ejection holes connected to the first gas supply line, the first gas supply line being provided at a reaction chamber side of the shower plate,
second gas election holes connected to the second gas supply line, the second gas ejection holes being provided at the reaction chamber side of the shower plate, and
purging gas ejection holes connected to the purging gas supply line, the purging gas ejection holes being provided near the side wall of the reaction chamber in relation to the first and second gas ejection holes.

7. The apparatus according to claim 6,
wherein the first or second process gas is ammonia, the first purging gas is hydrogen, and the second purging gas is nitrogen.

8. The apparatus according to claim 6, further comprising:
a first purging gas supply line connected to the purging gas supply line, the first purging gas supply line having a first mass flow controller, the first purging gas supply line supplying the first purging gas;
a second purging gas supply line connected to the purging gas supply line, the second purging gas supply line having a second mass flow controller, the second purging gas supply line supplying the second purging gas; and
a control unit controlling the first mass flow controller and the second mass flow controller.

9. A vapor phase growth method using a vapor phase growth apparatus including a reaction chamber, a shower plate disposed in the upper portion of the reaction chamber so as to supply a gas into the reaction chamber, and a support portion provided below the shower plate inside the reaction chamber so as to place a substrate thereon, the method comprising:
placing the substrate on the support portion;
heating the substrate;
ejecting a plurality of kinds of process gases for a film formation process from an inner area of the shower plate;
ejecting a mixed gas obtained by mixing a first purging gas selected from hydrogen and an inert gas and having a molecular weight smaller than that of an average molecular weight of the plurality of kinds of process gases with a second purging gas having a molecular weight larger than the average molecular weight from an outer area of the shower plate; and
forming a semiconductor film on the surface of the substrate.

10. The method according to claim 9,
wherein organic metal and ammonia are included in the plurality of kinds of process gases, the first purging gas is hydrogen, and the second purging gas is nitrogen.

11. The method according to claim 9,
wherein an average molecular weight of the mixed gas is equal to or larger than 80% and equal to or smaller than 120% of the average molecular weight of the plurality of kinds of process gases.
